(19) United States
(12) Patent Application Publication
(10) Pub. No.: US 2025/0072065 A1
(43) Pub. Date: Feb. 27, 2025

(54) FIELD EFFECT TRANSISTOR WITH ISOLATED SOURCE/DRAINS AND METHOD

(71) Applicant: Taiwan Semiconductor Manufacturing Co., Ltd., Hsinchu (TW)

(72) Inventors: Jung-Hung CHANG, Hsinchu (TW); Shih-Cheng CHEN, Hsinchu (TW); Chia-Hao YU, Hsinchu (TW); Chia-Cheng TSAI, Hsinchu (TW); Kuo-Cheng CHIANG, Hsinchu (TW); Chih-Hao WANG, Hsinchu (TW)

(21) Appl. No.: 18/405,526

(22) Filed: Jan. 5, 2024

Related U.S. Application Data
(60) Provisional application No. 63/520,691, filed on Aug. 21, 2023.

(51) Int. Cl. H01L 29/06; H01L 21/764; H01L 29/08; H01L 29/423; H01L 29/66; H01L 29/775

(52) U.S. Cl. CPC H01L 29/0653; H01L 21/764; H01L 29/0673; H01L 29/0847; H01L 29/42392; H01L 29/66439; H01L 29/66545; H01L 29/775

(57) ABSTRACT

A device includes: a substrate; a stack of semiconductor channels on the substrate; a gate structure wrapping around the semiconductor channels; a source/drain region abutting the semiconductor channels; and a hybrid structure between the source/drain region and the substrate. The hybrid structure includes: a first semiconductor layer under the source/drain region; and an isolation region extending vertically from an upper surface of the first semiconductor layer to a level above a bottom surface of the first semiconductor layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagrammatic cross-sectional side view of a portion of an IC device according to embodiments of the present disclosure.

FIGS. 2A-16 are views of various embodiments of an IC device of at various stages of fabrication according to various aspects of the present disclosure.

FIG. 17 is a flowchart of a method of forming an IC device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

Bulk substrate leakage and well isolation leakage are increasing with semiconductor scaling. A bottom isolation dielectric can be achieved by depositing a dielectric layer (e.g., SiN) between a source/drain epitaxy bottom and an undoped semiconductor to reduce effective capacitance (Ceff). However, direct current (DC) performance of a p-type FET may be degraded due to p-type epitaxy strain loss.

Embodiments of the disclosure effectively isolate the source/drain epitaxy and the substrate for both n-type and p-type FETs while maintaining an improved strain effect on the pFETs. In the embodiments, a sidewall dielectric layer is positioned between a substrate/fin and an undoped semiconductor feature to isolate the source/drain epitaxy and the semiconductor feature from the surrounding substrate, while keeping the undoped semiconductor surface exposed for pFET source/drain epitaxial growth to improve strain behavior. Bulk leakage and well isolation leakage can be efficiently suppressed by the sidewall dielectrics.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure structure.

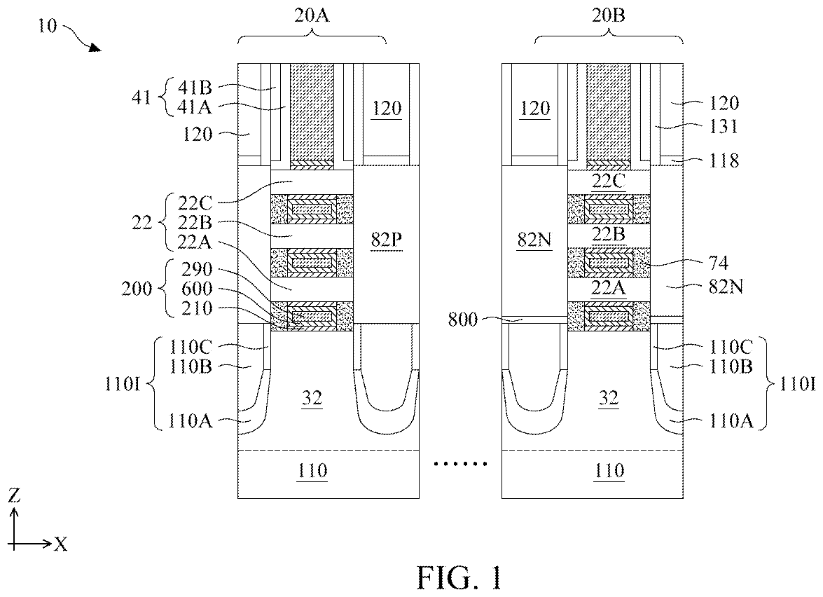

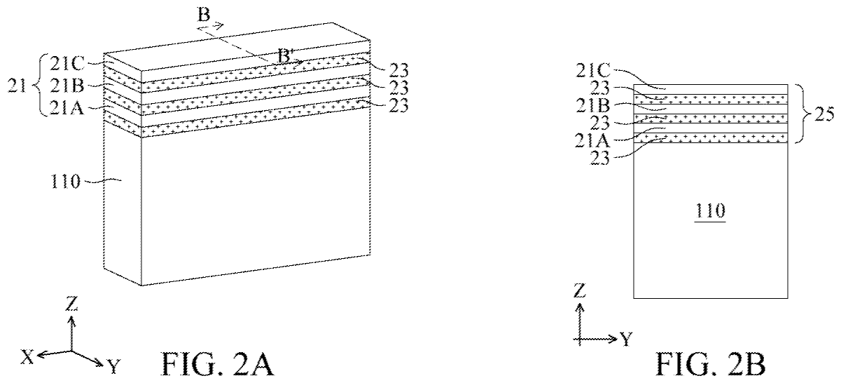

FIG. 1 illustrates a diagrammatic cross-sectional side view of a portion of a nanostructure device 10 in accordance with various embodiments. FIG. 1 illustrates a view in an X-Z plane, in which hybrid structures 110I that isolate respective semiconductor features 110B from a substrate 110 or fin 32 are positioned beneath source/drain regions 82P, 82N. The nanostructure device 10 of FIG. 1 is described in detail below to provide context for understanding the technical features and benefits of the various embodiments depicted in FIGS. 2A-16. Source/drain region(s) may refer to a source or a drain, individually or collectively dependent upon the context.

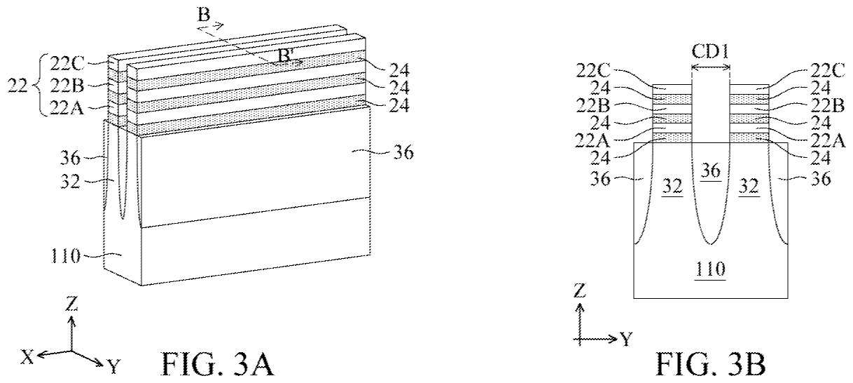

Referring to FIG. 1, nanostructure devices 20A, 20B may be or include one or more N-type FETs (NFETs) or P-type FETs (PFETs). The nanostructure devices 20A, 20B are formed over and/or in a substrate 110, and generally include gate structures 200 straddling and/or wrapping around semiconductor channels 22A, 22B, 22C, alternately referred to as “nanostructures,” located over semiconductor fins 32 protruding from, and separated by, isolation structures 36 (see FIG. 3B). The gate structure 200 controls electrical current flow through the channels 22A, 22B, 22C.

The nanostructure devices 20A, 20B are shown including three channels 22A, 22B, 22C, which are laterally abutted by source/drain features 82N, 82P, and covered and surrounded by the gate structure 200. Generally, the number of channels 22 is two or more, such as three or four or more. The gate structure 200 controls flow of electrical current through the channels 22A, 22B, 22C to and from the source/drain features 82N, 82P based on voltages applied at the gate structure 200 and at the source/drain features 82N, 82P.

In some embodiments, the fin structure 32 includes silicon. In some embodiments, the nanostructure device 20B includes an NFET, and the source/drain features 82N thereof include silicon phosphorous (SiP), SiAs, SiSb, SiPAs, SiP:As:Sb, combinations thereof, or the like. In some embodiments, the nanostructure device 20A includes a PFET, and the source/drain features 82P thereof include silicon germanium (SiGe), either undoped or doped to form, for example, SiGe:B, SiGe:B:Ga, SiGe:Sn, SiGe:B:Sn, or another appropriate semiconductor material. Generally, the source/drain features 82N, 82P may include any combination of appropriate semiconductor material(s) and appropriate dopant(s).

The channels 22A, 22B, 22C each include a semiconductive material, for example silicon or a silicon compound, such as silicon germanium, or the like. The channels 22A, 22B, 22C are nanostructures (e.g., having sizes that are in a range of a few nanometers) and may also each have an elongated shape and extend in the X-direction. In some embodiments, the channels 22A, 22B, 22C each have a nanowire (NW) shape, a nanosheet (NS) shape, a nanotube (NT) shape, or other suitable nanoscale shape. The cross-sectional profile of the channels 22A, 22B, 22C may be rectangular, round, square, circular, elliptical, hexagonal, or combinations thereof.

In some embodiments, the lengths (e.g., measured in the X-direction) of the channels 22A, 22B, 22C may be different from each other, for example due to tapering during a fin etching process (see FIGS. 3A, 3B). In some embodiments, length of the channel 22C may be less than a length of the channel 22B, which may be less than a length of channel 22A. The channels 22A, 22B, 22C each may not have uniform thickness (e.g., along the X-axis direction), for example due to a channel trimming process used to expand spacing (e.g., measured in the Z-axis direction) between the channels 22A, 22B, 22C to increase gate structure fabrication process window. For example, a middle portion of each of the channels 22A, 22B, 22C may be thinner than the two ends of each of the channels 22A, 22B, 22C. Such shape may be collectively referred to as a “dog-bone” shape.

In some embodiments, the spacing between the channels 22A, 22B, 22C (e.g., between the channel 22B and the channel 22A or the channel 22C) is in a range between about 8 nanometers (nm) and about 12 nm, though ranges exceeding or below the said range may also be beneficial. In some embodiments, a thickness (e.g., measured in the Z-direction) of each of the channels 22A, 22B, 22C is in a range between about 5 nm and about 8 nm, though ranges exceeding or below the said range may also be beneficial. In some embodiments, a width (e.g., measured in the Y-direction, shown in FIG. 1E, orthogonal to the X-Z plane) of each of the channels 22A, 22B, 22C is at least about 8 nm, however the width may be less than 8 nm in some embodiments.

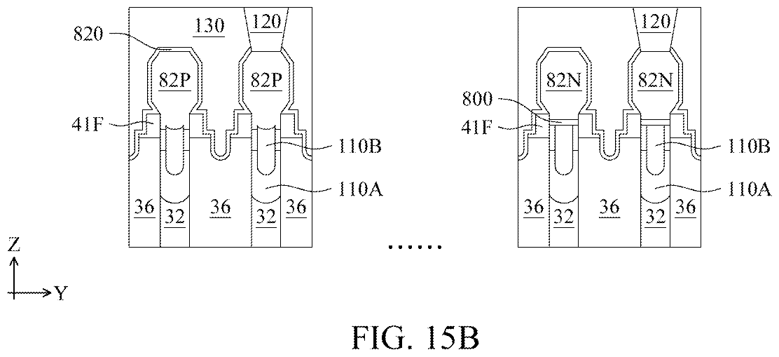

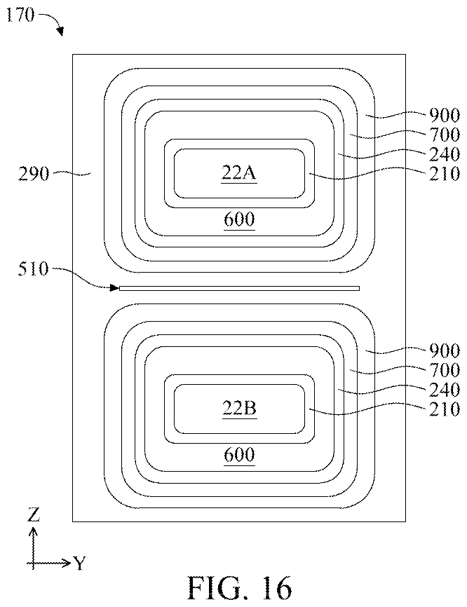

The gate structure 200 is disposed over and between the channels 22A, 22B, 22C, respectively. In some embodiments, the gate structure 200 is disposed over and between the channels 22A, 22B, 22C, which are silicon channels for N-type devices or silicon germanium channels for P-type devices. In some embodiments, the gate structure 200 includes an interfacial layer (IL) 210, one or more gate dielectric layers 600 on the interfacial layer 210, optionally one or more work function tuning layers 900 (see FIG. 16) on the gate dielectric layer 600 and a metal core layer 290 on the gate dielectric layer 600 and optionally on the work function tuning layer 900.

The interfacial layer 210, which may be an oxide of the material of the channels 22A, 22B, 22C, is formed on exposed areas of the channels 22A, 22B, 22C and the top surface of the fin 32. The interfacial layer 210 promotes adhesion of the gate dielectric layers 600 to the channels 22A, 22B, 22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance. In some embodiments, the interfacial layer 210 is doped with a dipole, such as lanthanum, for threshold voltage tuning.

In some embodiments, the gate dielectric layer 600 includes at least one high-k gate dielectric material, which may refer to dielectric materials having a high dielectric constant that is greater than a dielectric constant of silicon oxide (k≈3.9). Example high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A. The gate dielectric layer 600 may be a single layer or a multilayer.

The gate structure 200 also includes metal core layer 290. The metal core layer 290 may include a conductive material such as Co, W, Ru, combinations thereof, or the like. In some embodiments, the metal core layer 290 is or includes a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. Between the channels 22A, 22B, 22C, the metal core layer 290 is circumferentially surrounded (in the cross-sectional view) by the one or more work function metal layers 900, which are then circumferentially surrounded by the gate dielectric layers 600, which are circumferentially surrounded by the interfacial layer 210. The gate structure 200 may also include a glue layer that is formed between the one or more work function layers 900 and the metal core layer 290 to increase adhesion. The glue layer is not specifically illustrated in FIG. 1 for simplicity.

The nanostructure devices 20A, 20B may further include source/drain contacts 120 that are formed over the source/drain features 82N, 82P. The source/drain contacts 120 may include a core layer that is or includes a conductive material such as tungsten, ruthenium, cobalt, copper, titanium, titanium nitride, tantalum, tantalum nitride, iridium, molybdenum, nickel, aluminum, or combinations thereof. The core layer may be surrounded by one or more liner (or, “barrier”) layers, such as SiN or TiN, which help prevent or reduce diffusion of materials from and into the source/drain contacts 120. In some embodiments, height of the source/drain contacts 120 may be in a range of about 1 nm to about 50 nm.

Silicide layers 118 are positioned between the source/drain features 82N, 82P and the source/drain contacts 120, at least to reduce the source/drain contact resistance. In some embodiments, the silicide layer 118 is or includes TiSi, CrSi, TaSi, MoSi, ZrSi, HfSi, ScSi, Ysi, HoSi, TbSI, GdSi, LuSi, DySi, ErSi, YbSi, or the like. In some embodiments, the silicide layer 118 is or includes NiSi, CoSi, MnSi, Wsi, FeSi, RhSi, PdSi, RuSi, PtSi, IrSi, OsSi, or the like. The silicide layer 118 may have thickness in a range of about 1 nm to about 10 nm. Thickness lower than about 1 nm may lead to an insufficient reduction in contact resistance. Thickness above about 10 nm may cause electrical shorting with the nanostructures 22. In some embodiments, the silicide layer 118 is present below, and in contact with, etch stop layer 131.

The nanostructure devices 20A, 20B may further include an interlayer dielectric (ILD, not depicted). The ILD provides electrical isolation between the various components of the nanostructure devices 20A, 20B discussed above, for example between neighboring pairs of the source/drain contacts 120. An etch stop layer 131 may be formed prior to forming the ILD and may be positioned laterally between the ILD and the gate spacers 41 and vertically between the ILD and the source/drain features 82N, 82P. In some embodiments, the etch stop layer 131 is or includes SiN, SiCN, SiC, SiOC, SiOCN, HfO2, ZrO2, ZrAlOx, HfAlOx, HfSiOx, Al2O3, or other suitable material. In some embodiments, thickness of the etch stop layer is in a range of about 1 nm to about 5 nm. In some embodiments, where the ILD is not present (e.g., is removed completely prior to formation of the source/drain contacts 120), the etch stop layer 131 may be in contact with the source/drain contact 120. The etch stop layer 131 may be trimmed, for example, in the X-axis direction prior to formation of the source/drain contact 120 to improve fill quality of the source/drain contact 120.

The nanostructure devices 20A, 20B include gate spacers 41 that are disposed on sidewalls of the metal core layer 290, the gate dielectric layer 600 and the IL 210 above the channel 22A, and inner spacers 74 that are disposed on sidewalls of the IL 210 and/or the gate dielectric layer 600 between the channels 22A, 22B, 22C. The inner spacers 74 are also disposed between the channels 22A, 22B, 22C. In the embodiment depicted in FIG. 1, the gate spacers 41 include a first spacer layer 41A and a second spacer layer 41B on the first spacer layer 41A. The first and second spacer layers 41A, 41B may each include a dielectric material, for example a low-k material such as SiOCN, SiON, SiN, SiCN, SiOC or the like. In some embodiments, the second spacer layer 41B is not present. Material of the first and second spacer layers 41A, 41B may be the same as or different from each other. In some embodiments, an upper portion of the second spacer layer 41B (or the first spacer layer 41A when the second spacer layer 41B is not present) may be removed partially or fully to increase aspect ratio of an opening through which the source/drain region 82N, 82P is formed. FIG. 1 depicts an embodiment in which the upper portion of the second spacer layer 41B is not thinned.

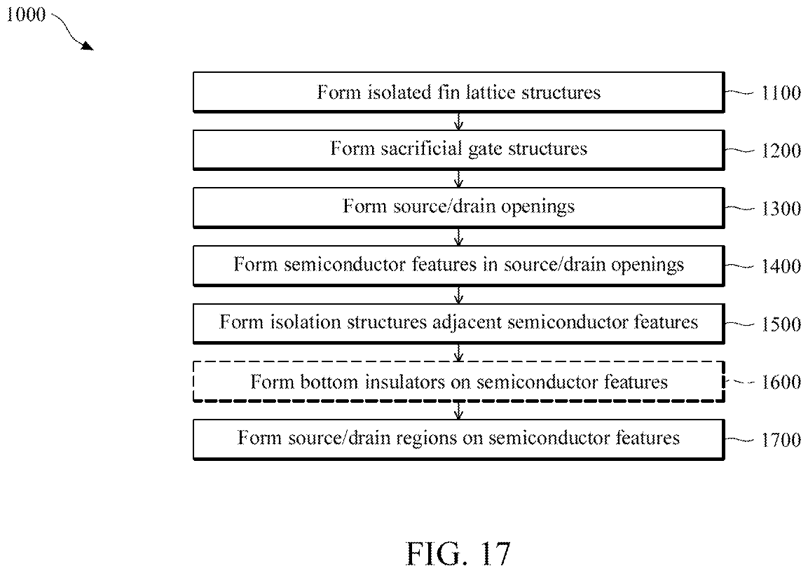

FIG. 17 depicts a flowchart of a method 1000 for forming an IC device or a portion thereof from a workpiece, according to one or more aspects of the present disclosure. Method 1000 is merely an example and not intended to limit the present disclosure to what is explicitly illustrated in method 1000. Additional acts can be provided before, during and after the method 1000 and some acts described can be replaced, eliminated, or moved around for additional embodiments of the method. Not all acts are described herein in detail for reasons of simplicity. Method 1000 is described below in conjunction with fragmentary perspective and/or cross-sectional views of a workpiece, shown in FIGS. 2A-16, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 2A through 16 are views of intermediate stages in the manufacturing of FETs, such as nanostructure FETs, in accordance with some embodiments.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B (collectively referred to as first semiconductor layers 21) and second semiconductor layers 23. In some embodiments, the first semiconductor layers 21 may be formed of a first semiconductor material suitable for n-type nano-FETs, such as silicon, silicon carbide, or the like, and the second semiconductor layers 23 may be formed of a second semiconductor material suitable for p-type nano-FETs, such as silicon germanium or the like. Each of the layers 21, 23 of the multi-layer stack 25 may be epitaxially grown using a process such as chemical vapor deposition (CVD), atomic layer deposition (ALD), vapor phase epitaxy (VPE), molecular beam epitaxy (MBE), or the like.

Three layers of each of the first semiconductor layers 21 and the second semiconductor layers 23 are illustrated. In some embodiments, the multi-layer stack 25 may include fewer or additional pairs of the first semiconductor layers 21 and the second semiconductor layers 23. Although the multi-layer stack 25 is illustrated as including a second semiconductor layer 23 as the bottommost layer, in some embodiments, the bottommost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIG. 3A and FIG. 3B, fins 32 are formed in the substrate 110 and nanostructures 22, 24 are formed in the multi-layer stack 25 corresponding to act 1100 of FIG. 17. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels 22” below) are formed from the first semiconductor layers 21, and second nanostructures 24 are formed from the second semiconductor layers 23. Distance CD1 between adjacent fins 32 and nanostructures 22, 24 may be from about 18 nm to about 100 nm. A portion of the device 10 is illustrated in FIGS. 3A and 3B including two fins 32 for simplicity of illustration. The process 1000 illustrated in FIG. 17 may be extended to any number of fins, and are not limited to the two fins 32 shown in FIGS. 3A-16.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIG. 3A and 3B, isolation regions or features 36, which may be shallow trench isolation (STI) regions or features, are formed adjacent the fins 32. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

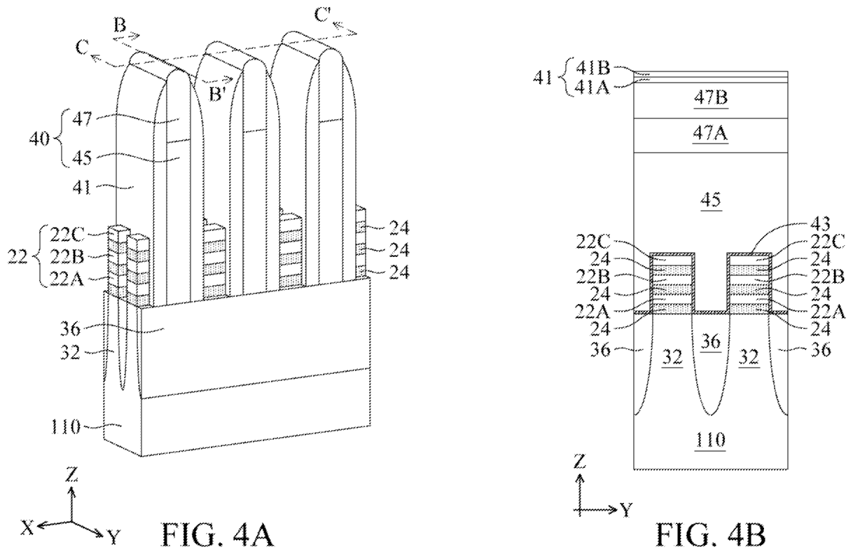

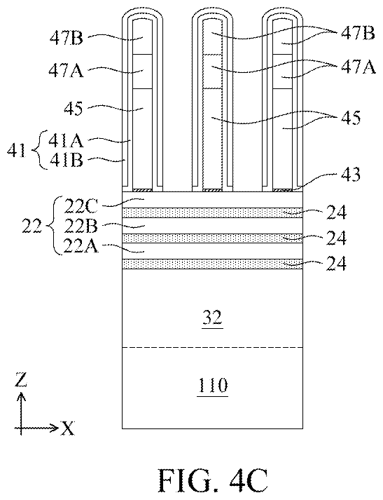

In FIGS. 4A-4C, dummy or sacrificial gate structures 40 are formed over the fins 32 and/or the nanostructures 22, 24, corresponding to act 1200 of FIG. 17. A dummy or sacrificial gate layer 45 is formed over the fins 32 and/or the nanostructures 22, 24. The dummy gate layer 45 may be or include materials that have a high etching selectivity relative to the isolation regions 36. The dummy gate layer 45 may be a conductive, semiconductive or non-conductive material and may be or include amorphous silicon, polycrystalline-silicon (polysilicon), poly-crystalline silicon-germanium (poly-SiGe), metallic nitrides, metallic silicides, metallic oxides, and metals. The dummy gate layer 45 may be deposited by physical vapor deposition (PVD), CVD, sputter deposition, or other techniques for depositing the selected material. A mask layer 47 is formed over the dummy gate layer 45, and may include, for example, silicon nitride, silicon oxynitride, or the like. In some embodiments, a gate dielectric layer 43 is formed before the dummy gate layer 45 between the dummy gate layer 45 and the fins 32 and/or the nanostructures 22, 24. In some embodiments, the mask layer 47 includes a first mask layer 47A in contact with the dummy gate layer 45, and a second mask layer 47B overlying and in contact with the first mask layer 47A. The first mask layer 47A may be or include the same or different material as that of the second mask layer 47B.

A spacer layer 41 is formed over sidewalls of the mask layer 47 and the dummy gate layer 45. The spacer layer 41 is or includes an insulating material, such as SiOCN, SiOC, SiCN or the like (or any of the materials described with reference to FIG. 1) and may have a single-layer structure or a multi-layer structure including a plurality of dielectric layers, in accordance with some embodiments. The spacer layer 41 may be formed by depositing a spacer material layer (not shown) over the mask layer 47 and the dummy gate layer 45. Portions of the spacer material layer between dummy gate structures 40 are removed using an anisotropic etching process, in accordance with some embodiments. In some embodiments, as shown in detail in FIGS. 4B, 4C, the spacer layer 41 includes a first spacer layer 41A in contact with the nanostructure 22C, the gate dielectric layer 43, the dummy gate layer 45 and the first and second mask layers 47A, 47B. A second spacer layer 41B of the spacer layer 41 may be in contact with the first spacer layer 41A. The first spacer layer 41A may be or include the same or different material as that of the second spacer layer 41B.

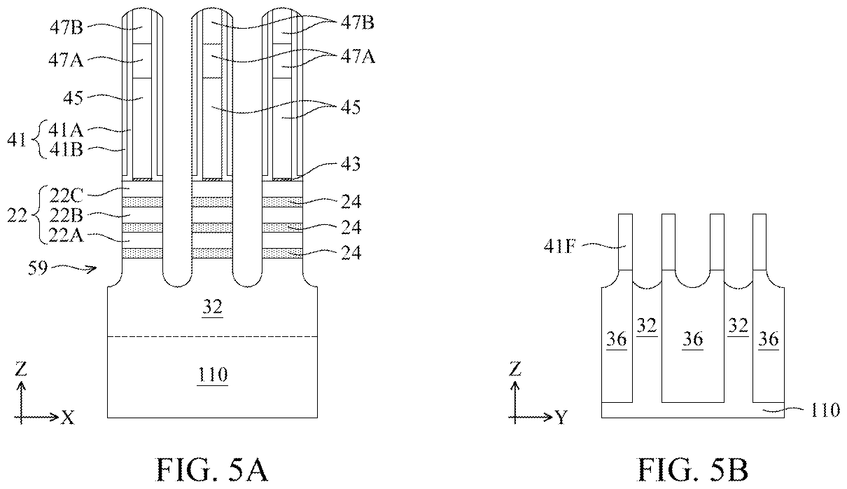

In FIGS. 5A and 5B, source/drain openings 59 are formed by performing an etching process to etch the portions of protruding fins 32 and/or nanostructures 22, 24 that are not covered by dummy gate structures 40, corresponding to act 1300 of FIG. 17. The recessing may be anisotropic, such that the portions of fins 32 directly underlying dummy gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments, as depicted in FIG. 5B. FIG. 5A depicts three vertical stacks of nanostructures 22, 24 following the etching process for simplicity. In general, the etching process may be used to form fewer or additional vertical stacks of nanostructures 22, 24 over the fins 32 than those depicted. In some embodiments, the second mask layer 47B is exposed following the etching process, for example, due to removal of upper portions of the spacer layers 41A, 41B during the etching process. FIG. 5B depicts fin spacers 41F which are portions of the first and/or second spacer layers 41A, 41B that overlie the isolation regions 36 adjacent to respective fins 32.

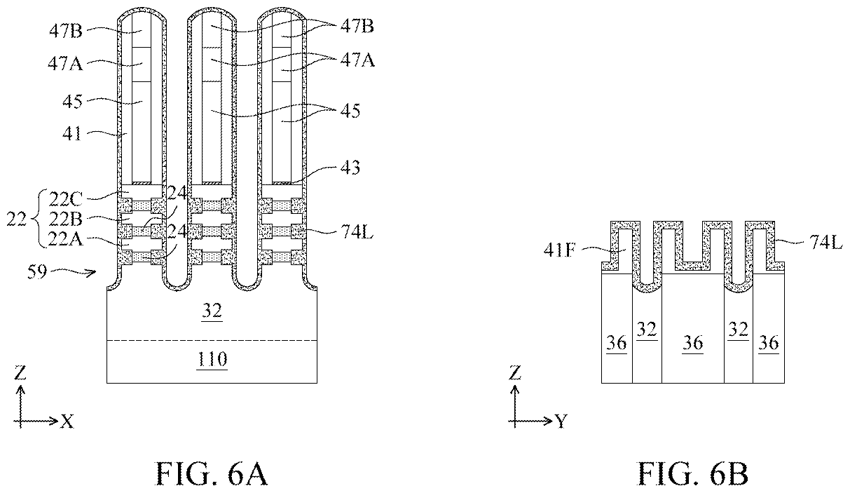

FIGS. 6A-13E depict formation of hybrid structures 110I in the source/drain openings 59, corresponding to acts 1400 and 1500 and optional act 1600 of FIG. 17.

In FIGS. 6A, 6B, a selective etching process is performed to recess end portions of the nanostructures 24 exposed by openings in the spacer layer 41 without substantially attacking the nanostructures 22. After the selective etching process, recesses are formed in the nanostructures 24 at locations where the removed end portions used to be. Then, following formation of the recesses 64, an inner spacer layer 74L is formed to fill (partially or entirely) the recesses in the nanostructures 22 formed by the previous selective etching process. The inner spacer layer 74L may be a suitable dielectric material, such as silicon carbon nitride (SiCN), silicon oxycarbonitride (SiOCN), or the like, formed by a suitable deposition method such as PVD, CVD, ALD, or the like.

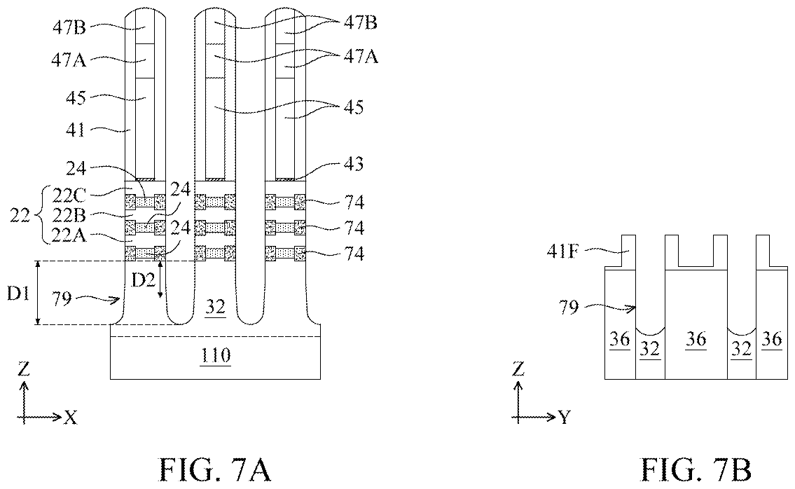

In FIGS. 7A and 7B, following formation of the inner spacer layer 74L, an etching process, such as an anisotropic etching process, is performed to remove portions of the inner spacer layer 74 disposed outside the recesses, for example, on sidewalls of the nanostructures 22 and the fins 32. The remaining portions of the inner spacer layer 74L (e.g., portions disposed inside the recesses in the nanostructures 24) form the inner spacers 74. During formation of the inner spacers 74 by the etching process, after breaking through a portion of the inner spacer layer 74L on an upper surface of the fin 32, the etching process may continue to form extended source/drain openings 79 that have depth that exceeds that of the source/drain openings 59. The resulting structure is shown in FIG. 7A.

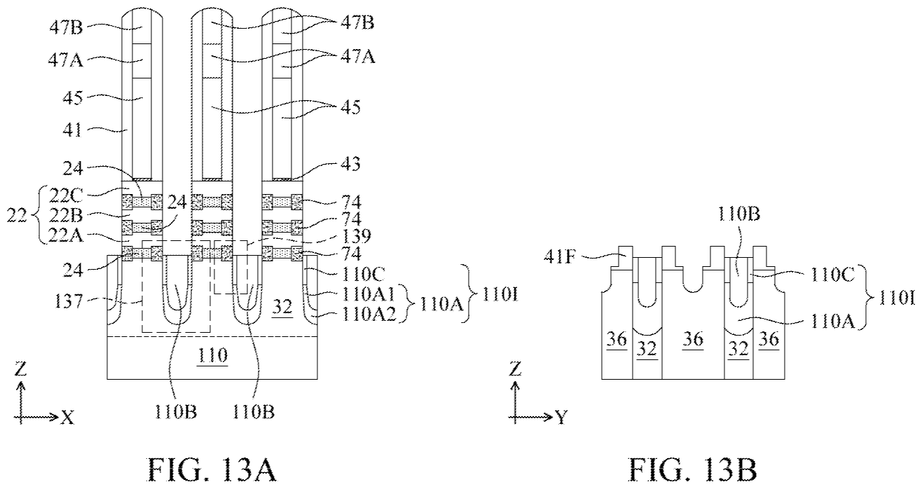

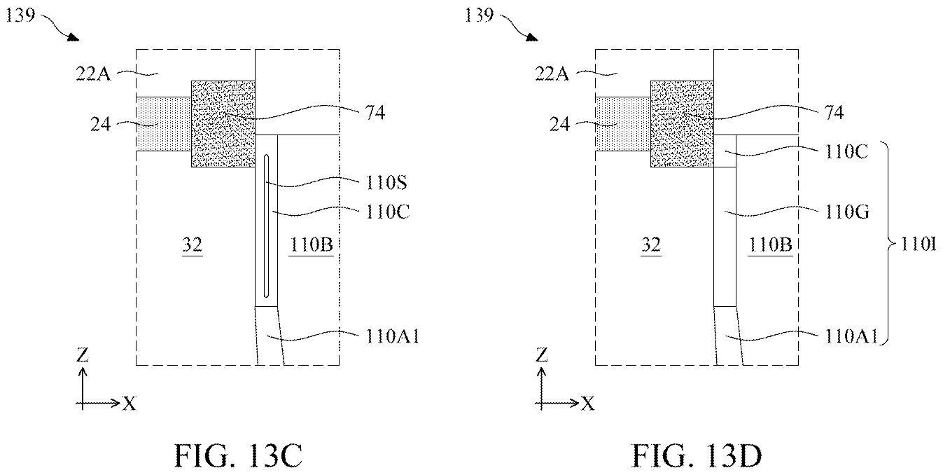

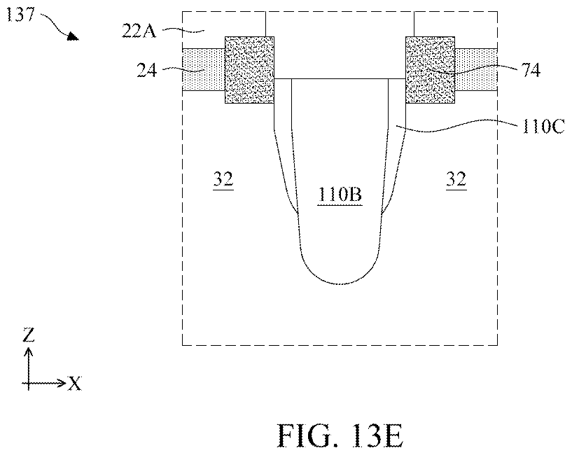

The extended source/drain openings 79 may extend to a first depth D1 that is below an upper surface of the fins 32. The first depth D1 may be measured from a bottom surface of the lowermost inner spacer 74, as depicted. In some embodiments, the first depth D1 may be in a range of about 25 nm to about 40 nm. The hybrid structure 110I described with reference to FIG. 1 and depicted in at least FIGS. 13A and 13B that isolates a semiconductor feature or mesa 110B from the substrate 110 or fin 32 is formed in the extended source/drain opening 79 in subsequent operations. The first depth D1 being less than about 25 nm may result in insufficient isolation (physical and/or electrical) between the semiconductor feature 110B and the substrate 110 or fin 32. The first depth D1 exceeding about 40 nm may result in difficulty forming layers in the extended source/drain opening 79 due to increased aspect ratio (depth/width) thereof.

The extended source/drain opening 79 may include a substantially straight or vertical upper portion that has second depth D2 that is less than the first depth D1. For example, the second depth D2 may be in a range of about 10 nm to about 20 nm. The upper portion may be associated with an isolation structure 110C. Namely, the isolation structure 110C may be formed as a substantially vertical structure instead of being tapered or slanted. This may be beneficial to increase thickness uniformity of the isolation structure 110C along its height (e.g., in the Z-axis direction).

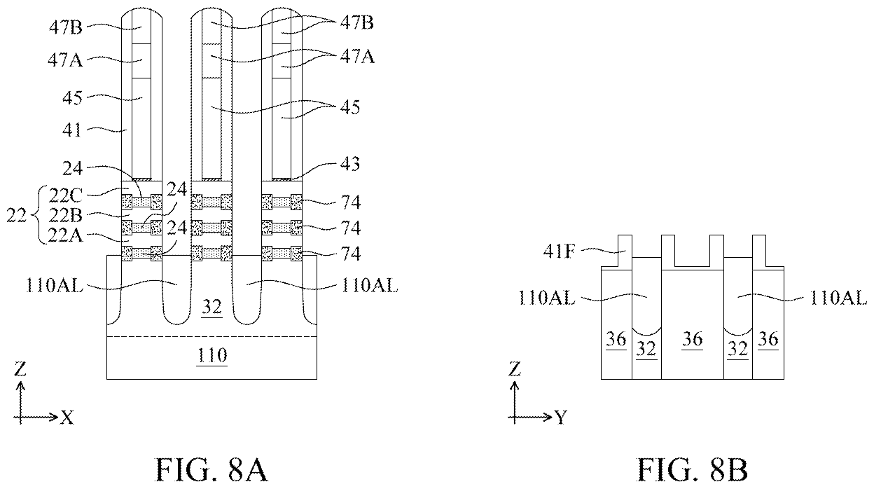

FIGS. 8A-10D depict formation of a semiconductor layer 110A or “second semiconductor layer 110A,” in accordance with various embodiments.

In FIGS. 8A, 8B, a first material layer 110AL is formed in the extended source/drain openings 79. The first material layer 110AL may be or include a material that has etching selectivity that is different from the substrate 110 and fin 32. For example, the substrate 110 and fin 32 may be silicon and the first material layer 110AL may be silicon germanium. In some embodiments, the first material layer 110AL is a dielectric material instead of a semiconductive material. When the first material layer 110AL is a silicon germanium (SiGe) layer, SiGe can be deposited in the extended source/drain openings 79. The deposition may include one or more operations, such as a CVD, which may be an Ultra-High Vacuum Chemical Vapor Deposition (UHV-CVD), which allows for improved control of deposition rate and purity of the SiGe first material layer 110AL. In some embodiments, precursor gases containing silicon and germanium may be introduced into a processing chamber, and a reaction therebetween forms the SiGe material, which deposits into the extended source/drain openings 79. In some embodiments, the deposition is selective, such that the SiGe preferentially deposits in the extended source/drain openings 79 without depositing on the nanosheets 22 and the inner spacers 74. Selective deposition may be achieved through selection of the precursor gases, temperature and pressure inside the processing chamber. As depicted in FIGS. 8A, 8B, the first material layer 110AL in each extended source/drain opening 79 may extend to a level that is above the upper surfaces of the fins 32 and the isolation regions 36.

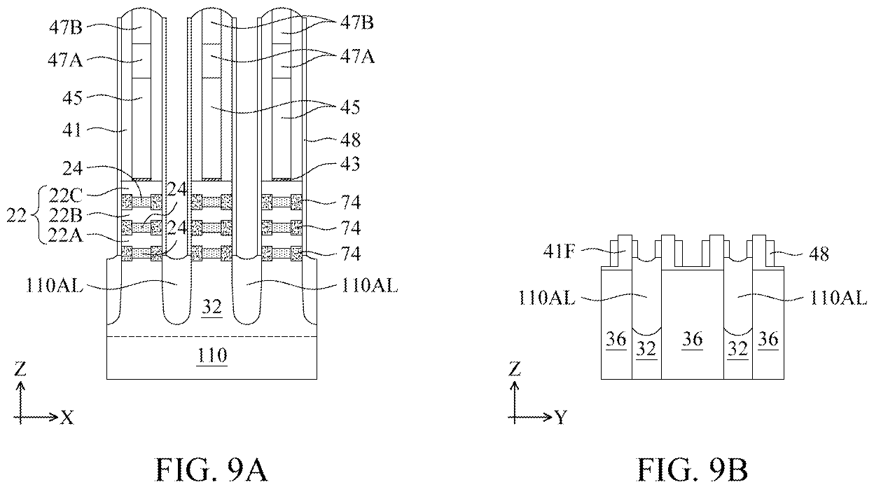

In FIGS. 9A, 9B, a mask layer 48 is formed on sidewall surfaces of the spacer layers 41, channels 22, inner spacers 74 and upper surfaces of the first material layer 110AL. The mask layer 48 may be a material layer that has different etch selectivity than the first material layer 110AL and the spacer layer 41. In some embodiments, the mask layer 48 is or includes a dielectric layer, such as silicon nitride, or another suitable dielectric layer, such as SiOC, SiC, Al2O3, TiN, HfO2, amorphous carbon or the like. The mask layer 48 may be deposited by Low-Pressure Chemical Vapor Deposition (LPCVD), Plasma-Enhanced Chemical Vapor Deposition (PECVD) or the like. Then, an etch process may be performed to remove (e.g., breakthrough) horizontal portions of the mask layer 48 that overlie the first material layer 110AL. The etch process may include phosphoric acid at high temperatures as an etchant for a wet etch process, or a fluorine-based plasma etchant for a dry etch process. Following the etch process, the upper surfaces of the first material layer 110AL may be exposed. In some embodiments, the mask layer 48 has thickness in a range of about 2 nm to about 4 nm, such as about 3 nm.

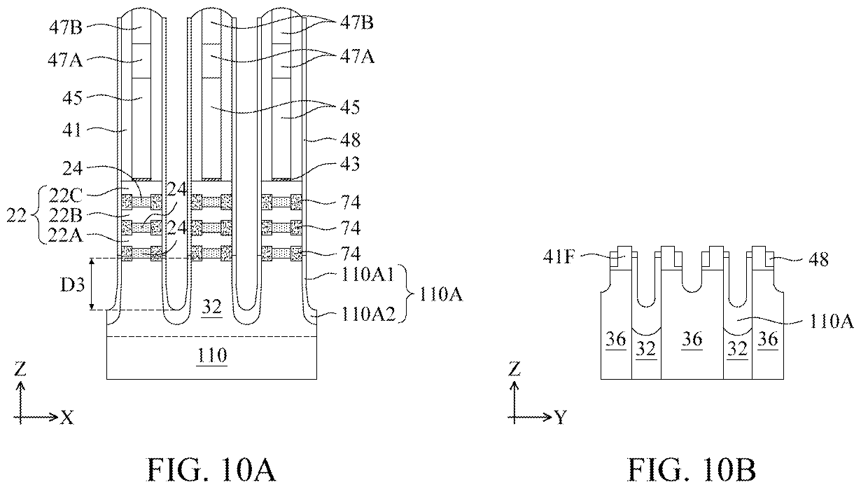

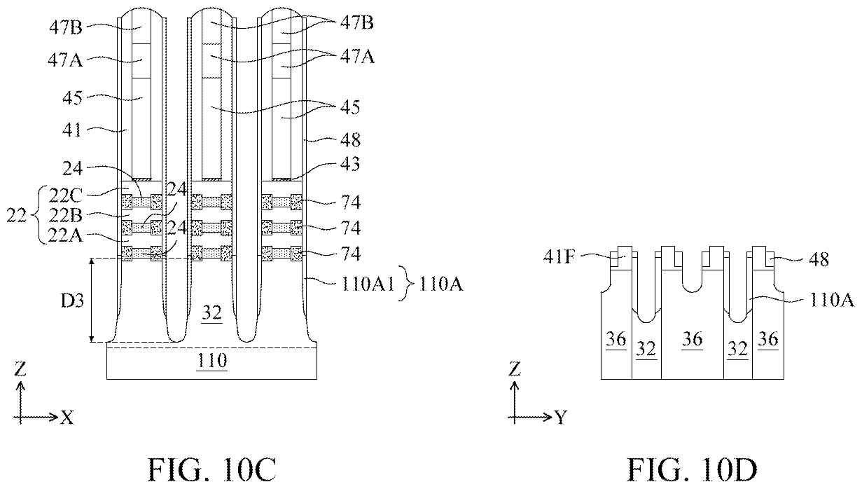

In FIGS. 10A-10D, portions of the first material layer 110AL exposed by the mask layer 48 are removed partially (FIGS. 10A, 10B) or entirely (FIGS. 10C, 10D).

In FIGS. 10A, 10B, the portions of the first material layer 110AL are removed to a third depth D3 that is between the first depth D1 and the second depth D2. In some embodiments, the third depth D3 is in a range of about 20 nm to about 35 nm. Following the removal, a first material layer 110A is formed. The first material layer 110A may include a vertical or straight upper portion 110A1 that is below the mask layer 48 and a lower portion 110A2 that is below the upper portion 110A1. Thickness of the upper portion 110A1 may be in a range of about 2 nm to about 4 nm, such as about 3 nm, which may be substantially the same as that of the mask layer 48. Thickness of the lower portion 110A2 may be in a range of about 5 nm to about 15 nm, such as about 10 nm. In some embodiments, thickness of the lower portion 110A2 is not uniform. For example, horizontal portions of the lower portion 110A2 may be thicker than angled portions of the lower portion 110A2. The angled portions may have thickness that increases with increased proximity to the substrate 110.

Removal of the first material layer 110AL as depicted in FIGS. 10A-10D may be via an etch process that is directional or anisotropic, such that the upper portion 110A1 under the mask layer 48 is not substantially removed. In some embodiments, the etch process includes reactive ion etching (RIE), deep reactive ion etching (DRIE), inductively coupled plasma (ICP) etching, atomic layer etching (ALE) or the like. In FIGS. 10A, 10B, the etch process may stop prior to reaching the bottom of the first material layer 110AL.

In FIGS. 10C, 10D, the etch process may break through the bottom of the first material layer 110AL. In some embodiments, the etch process then continues into the fin 32 beneath the first material layer 110AL. In such embodiments, the third depth D3 may exceed the first depth D1. For example, the third depth D3 may be in a range of about 20 nm to about 50 nm. The third depth D3 may exceed the first depth D1 by at least about 5 nm, such as about 10 nm, 15 nm or another suitable value between 5 nm and 15 nm. When the etch process breaks through the bottom of the first material layer 110AL, the resulting first material layer 110A may include the upper portion 110A1 and may not include the lower portion 110A2, as depicted in FIG. 10C. It should be understood that the etch process when etching silicon germanium of the first material layer 110AL may proceed with different process conditions (e.g., reactants, temperature, pressure) than when etching silicon of the fin 32.

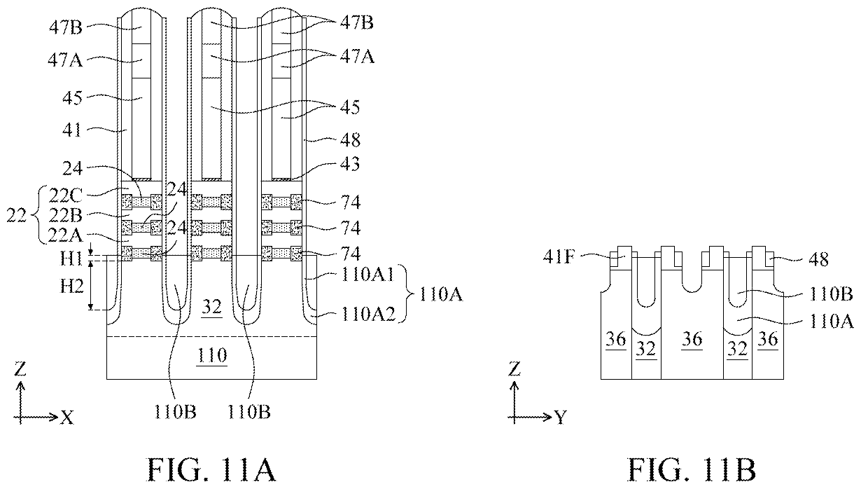

In FIGS. 11A, 11B, a first semiconductor layer 110B or “first semiconductor feature 110B” is formed on the first material layer 110AL, corresponding to act 1400 of FIG. 17. The first semiconductor layer 110B may be or include a semiconductor material, which may be an undoped semiconductor material, such as undoped silicon. The first semiconductor layer 110B may be formed with the mask layer 48 in place to avoid depositing silicon on the channels 22. The first semiconductor layer 110B may be formed by a suitable growth process, such as a chemical vapor deposition (CVD), molecular beam epitaxy (MPE) or the like. The first semiconductor layer 110B is a different material than the first material layer 110A, which is beneficial to remove the upper portion 110A1 without substantially removing the first semiconductor layer 110B. The first semiconductor layer 110B is a semiconductive material, which is beneficial to form pFET source/drains in subsequent operations that have improved strain, which improves DC performance.

In some embodiments, the first semiconductor layer 110B has an upper surface that is at a level substantially coplanar with an upper surface of the first material layer 110A. The first semiconductor layer 110B may have height H1+H2 that is in a range of about 22 nm to about 36 nm. The first height H1 is extension of the first semiconductor layer 110B above a bottom surface of the lowermost inner spacer 74. The second height H2 is extension of the first semiconductor layer 110B below the bottom surface of the lowermost inner spacer 74. In some embodiments, the inner spacers 74 have height in the Z-axis direction that is in a range of about 6 nm to about 10 nm.

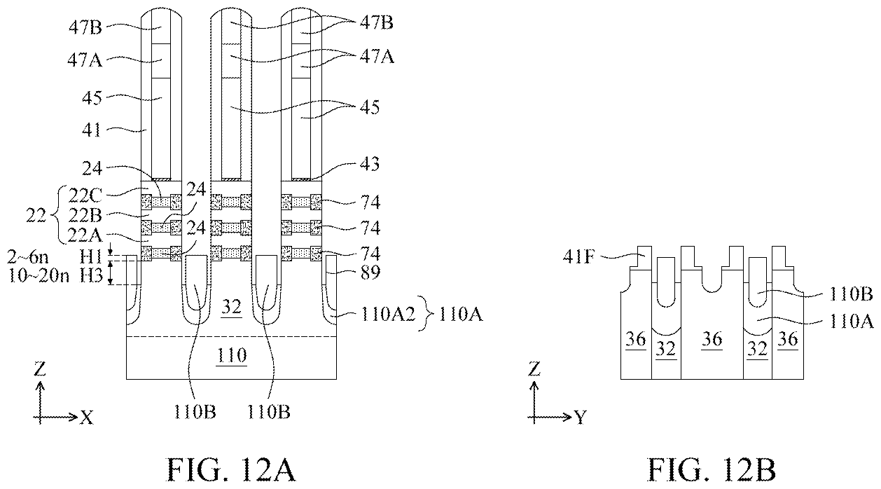

In FIGS. 12A, 12B, the upper portion 110A1 of the first material layer 110A is removed. Removal of the upper portion 110A1 may be via a suitable etch process, such as an isotropic wet or dry etch process that removes the upper portion 110A1 without substantially attacking the first semiconductor layer 110B. The mask layer 48 is removed prior to removing the upper portion 110A1. Following the removal, isolation openings 89 are formed. The isolation openings 89 may have height H1+H3 that is in a range of about 12 nm to about 26 nm. The third height H3 may be in a range of about 10 nm to about 20 nm. The third height H3 may be extension of the isolation openings 89 below the bottom surface of the lowermost inner spacer 74.

FIGS. 13A-13E depict formation of hybrid isolation structures 110I that can include first material layer 110A and isolation structures 110C, 110G in accordance with various embodiments, corresponding to act 1500 of FIG. 17.

In FIGS. 13A, 13B, an isolation structure 110C is formed in the isolation opening 89. The isolation structure 110C may be or include a dielectric material, such as SiOC, SiOCN, SiCN, SiN or the like. The isolation structure 110C may be a continuous layer of the dielectric material that entirely fills the isolation opening 89, as depicted in FIGS. 13A, 13B and is in direct contact with an upper surface of the first material layer 110A. Formation of the isolation structure 110C may be via a suitable deposition process followed by a suitable etch back process. The deposition process may be a LPCVD, PECVD, ALD or the like. Following deposition of the dielectric material into the isolation opening 89, excess material of the dielectric material may be removed by a suitable etch back process, such as a wet etch or dry etch that removes the dielectric material without substantially attacking other structure of the device 10.

In FIG. 13C, instead of filling the isolation opening 89 entirely, the isolation structure 110C may have a seam 110S therein. The seam 110S may be formed due to an upper portion of the isolation structure 110C merging prior to the isolation opening 89 being entirely filled. In some embodiments, the seam 110S includes air, vacuum, unreacted gases, a combination thereof, or the like.

In FIG. 13D, instead of filling the isolation opening 89 entirely, only an upper portion of the isolation opening 89 is filled with the isolation structure 110C and the remainder of the isolation opening 89 is an isolation gap 110G, which may be an air gap or may include vacuum, unreacted gases, or the like. The isolation gap 110G may be substantially free of the dielectric material of the isolation structure 110C. As depicted in FIG. 13D, the isolation structure 110C may extend to a depth that is substantially coplanar with the bottom surface of the lowermost inner spacer 74. In some embodiments, the isolation structure 110C extends to a depth that is somewhat above or below the bottom surface of the lowermost inner spacer 74. The isolation structure 110C may be offset from the first material layer 110A via the isolation gap 110G.

FIG. 13E is associated with the embodiment described with reference to FIGS. 10C, 10D, in which the etch process breaks through the first material layer 110A and extends into the fin 32. As depicted, the first semiconductor layer 110B extends to a level below the bottom of the isolation opening 89. Namely, the first semiconductor layer 110B inherits the shape of the opening depicted in FIGS. 10C, 10D. Then, the upper portion 110A1 of the first material layer 110A is removed similar to as described with reference to FIGS. 12A, 12B, except that the first material layer 110A may be removed entirely instead of leaving the lower portion 110A2 due to the lower portion 110A2 having been removed when the etch process broke through the first material layer 110A. In the embodiment depicted in FIG. 13E, the upper portion 110A1 is fully removed when forming the isolation opening 89. The isolation structure 110C may then be formed in the isolation opening 89, as shown. The isolation structure 110C may be any of the isolation structures 110C, 110G described with reference to FIGS. 13A-13D above.

In FIGS. 13A-13E, the isolation structure is described as including the isolation structure 110C that is a dielectric material. In some embodiments, the isolation structure 110C is not deposited, such that an isolation gap 110G is present, which may be the same as the isolation opening 89. This can be beneficial to simplify the manufacturing process by removing one deposition operation and one etch back operation.

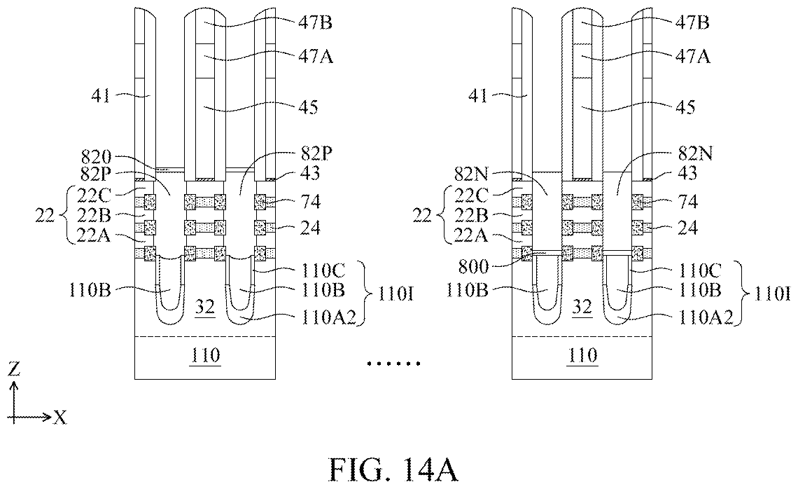

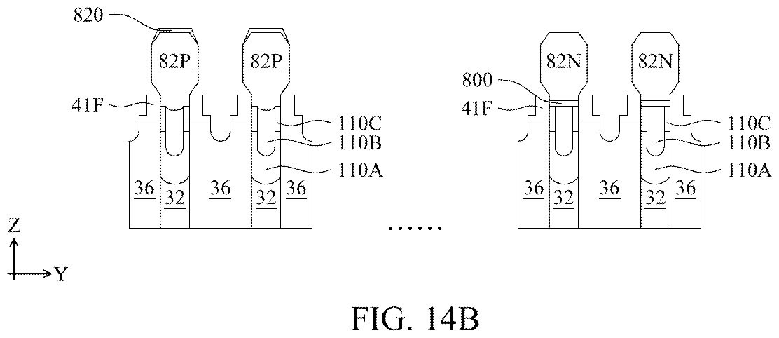

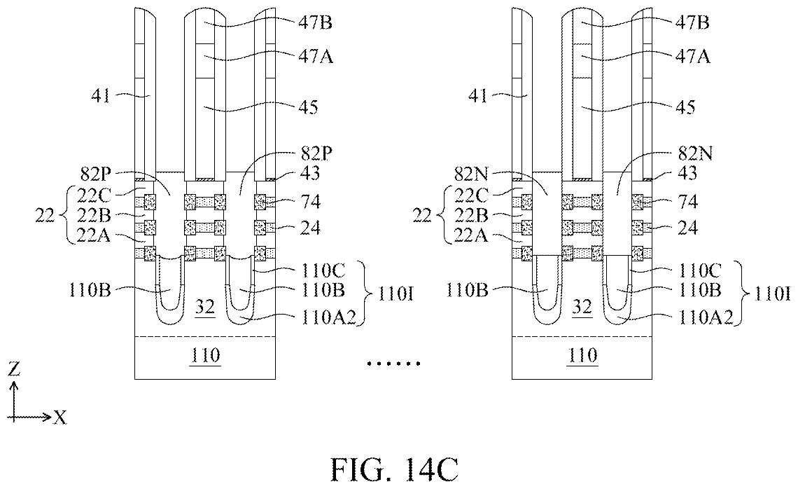

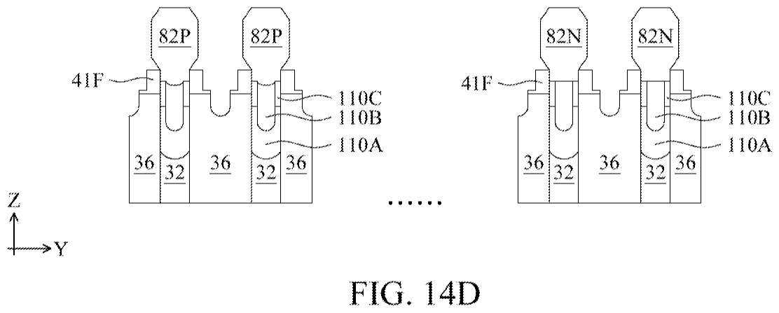

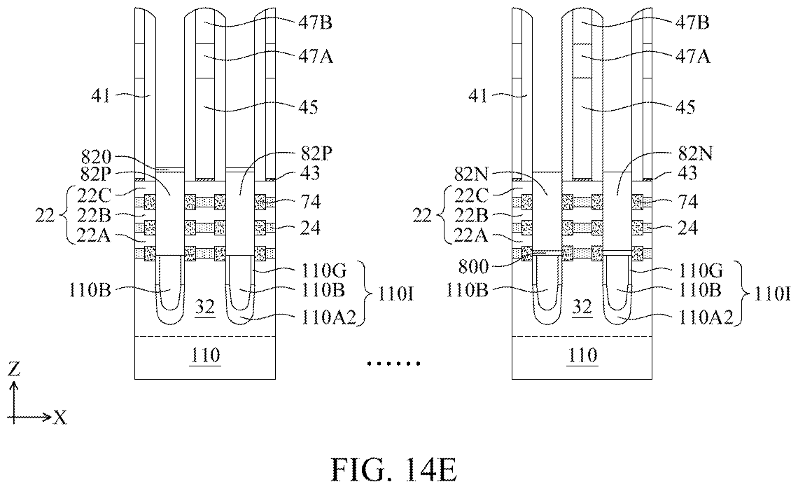

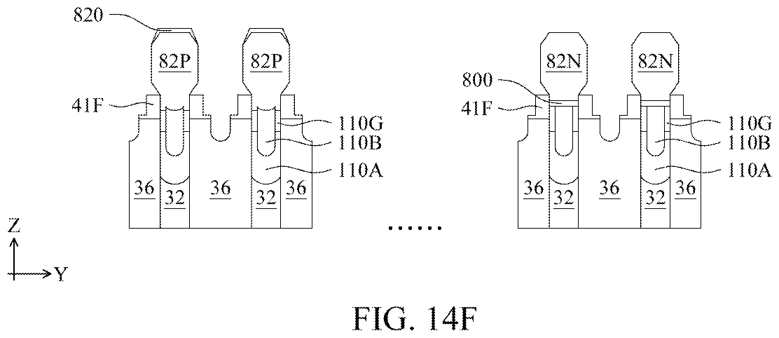

FIGS. 14A-14F depict formation of bottom insulators 800 and source/drain regions 82N, 82P or “source/drains 82N, 82P” in accordance with various embodiments, corresponding to acts 1600 and 1700 of FIG. 17. FIGS. 14A-14F depict formation of p-type source/drains 82P and n-type source/drains 82N, which may be different from each other in some respects. Namely, devices including n-type source/drains 82N may benefit from inclusion of the bottom insulator 800, whereas devices including p-type source/drains 82P may benefit from exclusion of the bottom insulator 800.

In FIGS. 14A, 14B, source/drain regions 82N, 82P are formed. In the illustrated embodiment, the source/drain regions 82P are epitaxially grown from epitaxial material(s). In some embodiments, the source/drain regions 82P exert stress in the respective channels 22A, 22B, 22C, thereby improving performance. The source/drain regions 82P are formed such that each dummy gate structure 40 is disposed between respective neighboring pairs of the source/drain regions 82P. In some embodiments, the spacer layer 41 separates the source/drain regions 82P from the dummy gate layer 45 by an appropriate lateral distance to prevent electrical bridging to subsequently formed gates of the resulting device. The source/drain regions 82P may be or include Si:B, Si:Ga, SiGe:B, SiGe:B:Ga, SiGe:Sn, SiGe:B:Sn or the like. The source/drain regions 82P may exert a compressive strain in the channel regions. The source/drain regions 82N, 82P may have surfaces raised from respective surfaces of the first semiconductor layer 110B and may have facets. Neighboring source/drain regions 82P may merge in some embodiments to form a singular source/drain region 82P adjacent two neighboring fins 32.

In the illustrated embodiment, following formation of the source/drain regions 82P, the optional bottom insulator 800 may be formed. Formation of the bottom insulator 800 may include a suitable deposition operation, such as an LPCVD, PECVD, ALD, or the like. The bottom insulator 800 may be or include SiN or another suitable dielectric material. Thickness of the bottom insulator 800 may be in a range of about 2 nm to about 4 nm. During formation of the bottom insulator 800, a dielectric layer 820 may be formed on the upper surface of the source/drain region 82P. The dielectric layer 820 may have the same composition (e.g., SiN) and thickness as those of the bottom insulator 800.

Following formation of the bottom insulator 800, the source/drain regions 82N are epitaxially grown from epitaxial material(s). Due to the bottom insulator 800, the source/drain regions 82N may grow from the channels 22 without growing from the first semiconductor layer 110B. In some embodiments, the source/drain regions 82N exert stress in the respective channels 22A, 22B, 22C, thereby improving performance. The source/drain regions 82N are formed such that each dummy gate structure 40 is disposed between respective neighboring pairs of the source/drain regions 82N. In some embodiments, the spacer layer 41 separates the source/drain regions 82N from the dummy gate layer 45 by an appropriate lateral distance to prevent electrical bridging to subsequently formed gates of the resulting device. The source/drain regions 82N may be or include SiP, SiAs, SiSb, SiPAs, SiP:As:Sb or the like. The source/drain regions 82N may exert a tensile strain in the channel regions due to presence of the bottom insulator 800. The source/drain regions 82N may have surfaces raised from respective surfaces of the fins 32 and may have facets. Neighboring source/drain regions 82N may merge in some embodiments to form a singular source/drain region 82N adjacent two neighboring fins 32.

FIGS. 14A, 14B also depict recessing of the nanosheets 22 and the first semiconductor layer 110B. In some embodiments, the nanosheets 22 are recessed slightly in the horizontal direction (e.g., the X-axis direction) and the first semiconductor layer 110B is recessed slightly in the vertical direction (e.g., the Z-axis direction). The recessing may be due to etching of the nanosheets 22 and first semiconductor layer 110B during etching of the upper portion 110A1 of the first material layer 110A.

In FIGS. 14C, 14D, the bottom insulator 800 and dielectric layer 820 are not formed. Namely, act 1600 of FIG. 17 may be omitted in some embodiments, which is depicted by dashed lines in FIG. 17. As such, the source/drain regions 82N, 82P grow from the first semiconductor layer 110B and the nanosheets 22 and are in direct contact with the first semiconductor layer 110B.

In FIGS. 14E, 14F, the bottom insulator 800 and dielectric layer 820 are formed and the isolation structure 110C is not formed and instead the isolation gap 110G is formed. When the bottom insulator 800 is formed, the isolation gap 110G is formed in the device having n-type source/drains 82N. When the p-type source/drains 82P are formed, the isolation gap 110G is formed in the device having p-type source/drains 82P. As such, in p-type devices, the isolation gap 110G may be adjacent the p-type source/drain 82N, the fin 32, the first semiconductor layer 110B and optionally the lower portion 110A2 of the first material layer 110A. In n-type devices, the isolation gap 110G may be adjacent the bottom insulator 800, the fin 32, the first semiconductor layer 110B and optionally the lower portion 110A2 of the first material layer 110A.

The embodiments described with reference to FIGS. 13A-14F can be combined. For example, the embodiment described with reference to FIG. 13E in which the lower portion 110A2 is not present and the first semiconductor layer 110B extends further into the fin 32 may be combined with the embodiment described with reference to FIG. 14E, 14F in which the isolation gap 110G is formed instead of the isolation structure 110C.

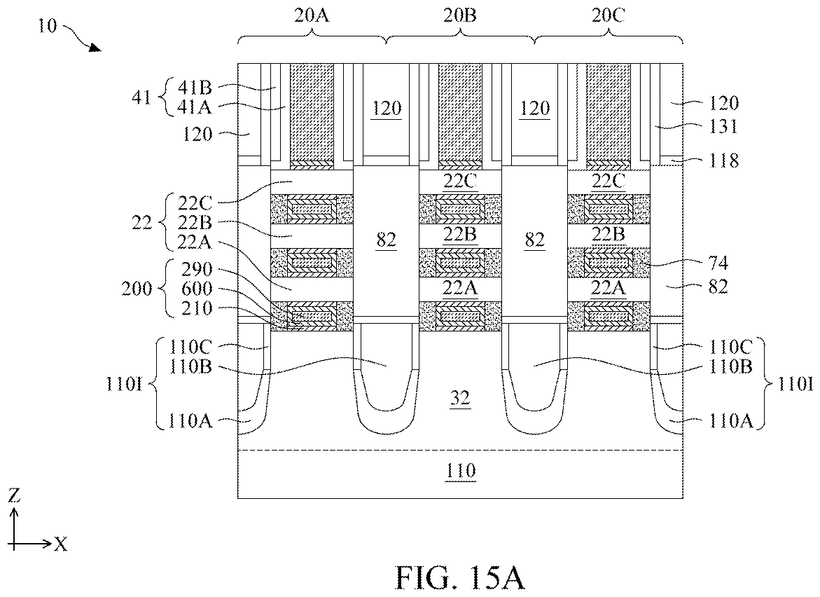

In FIGS. 15A, 15B, following formation of the source/drain regions 82N, 82P, the ILD 130 may be formed covering the source/drain regions 82N, 82P and abutting the spacer layer 41. In some embodiments, the ESL 131 is formed prior to forming the ILD 130. The ESL 131 may be formed by depositing a conformal thin layer of a dielectric material different from that of the ILD 130, such as one or more of SiN, SiCN, SiC, SiOC, SiOCN, HfO2, ZrO2, ZrAlOx, HfAlOx, HfSiOx, Al2O3, or other suitable material. Following deposition of the ESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG) or a combination thereof. The ILD may be deposited by spin-on coating, CVD, Flowable CVD (FCVD), PECVD, PVD, or another deposition process.

Then, active gate structures 200 may be formed. A planarization process, such as a chemical mechanical polishing (CMP) process, is performed on the ILD 130 and the ESL 131. The hard masks 47A, 47B and portions of the gate spacers 41 are also removed in the planarization process. After the planarization process, the dummy gate layers 45 are exposed. The top surfaces of the ILD 130 and the ESL 131 may be coplanar with the top surfaces of the dummy gate layers 45 and the gate spacers 41.

Next, the dummy gate layer 45 is removed in an etching process, so that recesses are formed. In some embodiments, the dummy gate layer 45 is removed by an anisotropic dry etch process. For example, the etching process may include a dry etch process using reaction gas(es) that selectively etch the dummy gate layer 45 without etching the spacer layer 41. The dummy gate dielectric 43, when present, may be used as an etch stop layer when the dummy gate layer 45 is etched. The dummy gate dielectric 43 may then be removed after the removal of the dummy gate layer 45.

The nanostructures 24 are removed to release the nanostructures 22. After the nanostructures 24 are removed, the nanostructures 22 form a plurality of nanosheets that extend horizontally (e.g., parallel to a major upper surface of the substrate 110). In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of NFETs, and nanostructures 22 may be removed and the nanostructures 24 may be patterned to form channel regions of PFETs. In some embodiments, the nanostructures 22 may be removed and the nanostructures 24 may be patterned to form channel regions of NFETs, and the nanostructures 24 may be removed and the nanostructures 22 may be patterned to form channel regions of PFETs. In some embodiments, the nanostructures 22 may be removed and the nanostructures 24 may be patterned to form channel regions of both PFETs and NFETs.

In some embodiments, the nanosheets 22 are reshaped (e.g., thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction (see FIG. 10C, for example).

Then, replacement gates 200 are formed. The gate structures 200 may be formed by a series of deposition operations, such as ALD cycles, that deposit the various layers of the gate structure 200 in the openings, described below with reference to FIG. 16.

FIG. 16 is a detailed view of a portion of the gate structure 200. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 16, in some embodiments, the first IL 210 includes an oxide of the semiconductor material of the substrate 110, e.g., silicon oxide. In other embodiments, the first IL 210 may include another suitable type of dielectric material. The first IL 210 has a thickness in a range between about 5 angstroms and about 50 angstroms.

Still referring to FIG. 16, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl4 and/or H2O as precursors. Such an ALD process may form the first gate dielectric layer 220 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices 20A, 20B.

With further reference to FIG. 16, the second IL 240 is formed on the gate dielectric layer 600, and the second work function layer 700 is formed on the second IL 240. The second IL 240 promotes better metal gate adhesion on the gate dielectric layer 600. In many embodiments, the second IL 240 further provides improved thermal stability for the gate structure 200, and serves to limit diffusion of metallic impurity from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAlON, HfZrO, or other suitable materials, in various embodiments. In a specific embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

Further in FIG. 16, after forming the second IL 240 and removing the high-k capping layer, the work function barrier layer 700 is optionally formed on the gate structure 200, in accordance with some embodiments. The work function barrier layer 700 is or comprises a metal nitride, such as TiN, WN, MoN, TaN, or the like. In a specific embodiment, the work function barrier layer 700 is TiN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices, and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TiN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 16 further illustrates the metal core layer 290. In some embodiments, a glue layer (not separately illustrated) is formed between the oxygen blocking layer of the work function metal layer and the metal core layer 290. The glue layer may promote and/or enhance the adhesion between the metal core layer 290 and the work function metal layer 900. In some embodiments, the glue layer may be formed of a metal nitride, such as TiN, TaN, MoN, WN, or another suitable material, using ALD. In some embodiments, thickness of the glue layer is between about 10 A and about 25 A. The metal core layer 290 may be formed on the glue layer, and may include a conductive material such as tungsten, cobalt, ruthenium, iridium, molybdenum, copper, aluminum, or combinations thereof. In some embodiments, the metal core layer 290 may be deposited using methods such as CVD, PVD, plating, and/or other suitable processes. In some embodiments, a seam 510, which may be an air gap, is formed in the metal core layer 290 vertically between the channels 22A, 22B, 22C. In some embodiments, the metal core layer 290 is conformally deposited on the work function metal layer 900. The seam 510 may form due to sidewall deposited film merging during the conformal deposition. In some embodiments, the seam 510 is not present between the neighboring channels 22A, 22B, 22C.

Following formation of the gate structures 200, source/drain openings may be formed in the ILD 130 and source/drain contacts 120 may be formed in the source/drain openings. The resulting structure is shown in FIGS. 15A, 15B. Silicide regions 118 and the source/drain contacts 120 are formed on the source/drain regions 82N, 82P.

In some embodiments, the silicide layers 118 are formed prior to formation of the source/drain contacts 120. For example, an N-type or P-type metal layer may be formed as a conformal thin layer over exposed portions of the source/drain regions 82N, 82P. The metal layer may be or include one or more of Ni, Co, Mn, W, Fe, Rh, Pd, Ru, Pt, Ir, Os or the like. In some embodiments, the metal layer is or includes one or more of Ti, Cr, Ta, Mo, Zr, Hf, Sc, Ys, Ho, Tb, Gd, Lu, Dy, Er, Yb or another suitable material. Following formation of the metal layer, the silicide layers 118 may be formed by annealing the device 10. Following the anneal, the silicide layers 118 may be or include one or more of NiSi, CoSi, MnSi, Wsi, FeSi, RhSi, PdSi, RuSi, PtSi, IrSi, OsSi, TiSi, CrSi, TaSi, MoSi, ZrSi, HfSi, ScSi, Ysi, HoSi, TbSl, GdSi, LuSi, DySi, ErSi, YbSi or the like. Silicide of the silicide layers 118 may diffuse into regions below the ESL 131. Thickness of the silicide layers 118 may be in a range of about 1 nm to about 10 nm. Below about 1 nm, contact resistance may be too high. Above about 10 nm, the silicide layers 118 may short with the channels 22B.

Following formation of the silicide layers 118, the source/drain contacts 120 are formed by filling the openings over the source/drain regions 82N, 82P with, for example, a liner layer and a fill layer. In some embodiments, the source/drain contacts 120 are formed by depositing a material that is or includes a conductive material such as Co, W, Ru, combinations thereof, or the like. In some embodiments, the source/drain contacts 120 are or include a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. The source/drain contacts 120 land on the silicide layer 118 and are in contact with the ESL 131. Description of the device 10 and illustration thereof in many of the figures is given with reference to GAAFETs including vertical stacks of the nanostructures 22. In some embodiments, the silicide layers 118 and the source/drain contacts 120 are formed in and on source/drain regions 82N, 82P of FinFET devices.

Additional processing may be performed to finish fabrication of the nanostructure devices 20. For example, gate contacts (or gate vias) may be formed to electrically couple to the gate structures 200. An interconnect structure may then be formed over the source/drain contacts 120 and the gate contacts. The interconnect structure may include a plurality of dielectric layers (including, for example, a second ILD) surrounding metallic features, including conductive traces and conductive vias, which form electrical connection between devices on the substrate 110, such as the nanostructure devices 20, as well as to IC devices external to the IC device 10.

Embodiments may provide advantages. By forming the isolation structure 110C or gap 110G, electrical isolation between the first semiconductor layers 110B and source/drain regions 82N, 82P is increased, such that the bottom isolation 800 may be omitted in the p-type device. As a result, the source/drain 82P may be grown from the first semiconductor layer 110B, which is beneficial to increase compressive strain in the channels 22. The bottom isolation 800 may be included in the n-type device so that tensile strain is exerted on the channels 22 thereof due to the source/drain 82N growing from the channels 22 without growing from the first semiconductor layer 110B.

In accordance with at least one embodiment, a device includes: a substrate; a stack of semiconductor channels on the substrate; a gate structure wrapping around the semiconductor channels; a source/drain region abutting the semiconductor channels; and a hybrid structure between the source/drain region and the substrate. The hybrid structure includes: a first semiconductor layer under the source/drain region; and an isolation region extending vertically from an upper surface of the first semiconductor layer to a level above a bottom surface of the first semiconductor layer.

In accordance with at least one embodiment, a device includes: a substrate and a first transistor including: a first stack of nanostructures on the substrate; a first source/drain that is adjacent the first stack of nanostructures, the first source/drain including a p-type semiconductor; and a first hybrid structure between the first source/drain and the substrate. The first hybrid structure includes: a first semiconductor feature, the first source/drain being in direct contact with the first semiconductor feature; and a first isolation region between the first semiconductor feature and the substrate. The device further includes a second transistor including: a second stack of nanostructures on the substrate; a second source/drain that is adjacent the second stack of nanostructures, the second source/drain including an n-type semiconductor; and a second hybrid structure between the second source/drain and the substrate. The second hybrid structure includes: a second semiconductor feature, the second source/drain being on the second semiconductor feature; and a second isolation region between the second semiconductor feature and the substrate.

In accordance with at least one embodiment, a method includes: forming a stack of nanostructures over a substrate; forming a source/drain opening to a first level below the stack of nanostructures; forming an extended source/drain opening by extending the source/drain opening to a second level below the first level; forming a first material layer in the extended source/drain opening; forming a semiconductor feature in the extended source/drain opening adjacent the first material layer; forming an isolation structure including forming an isolation opening in the first material layer; and forming a source/drain region on the semiconductor feature and on respective sidewalls of the stack of nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate;
a stack of semiconductor channels on the substrate;
a gate structure wrapping around the semiconductor channels;
a source/drain region abutting the semiconductor channels; and
a hybrid structure between the source/drain region and the substrate, the hybrid structure including:
a first semiconductor layer under the source/drain region; and
an isolation region extending vertically from an upper surface of the first semiconductor layer to a level above a bottom surface of the first semiconductor layer.

2. The device of claim 1, wherein the isolation region includes a dielectric material.

3. The device of claim 1, wherein the isolation region includes a void.

4. The device of claim 3, wherein the isolation region includes a dielectric material and the void is a seam in the dielectric material.

5. The device of claim 1, wherein the hybrid structure further includes:
a second semiconductor layer under the first semiconductor layer, the second semiconductor layer being a second material that is different than a first material of the first semiconductor layer.

6. The device of claim 5, wherein the isolation region includes:
a dielectric layer that extends to a second level above an upper surface of the second semiconductor layer; and
a void between the dielectric layer and the second semiconductor layer.

7. The device of claim 1, further comprising:
a bottom insulator between the source/drain region and the hybrid structure.

8. A device, comprising:
a substrate;
a first transistor including:
a first stack of nanostructures on the substrate;
a first source/drain that is adjacent the first stack of nanostructures, the first source/drain including a p-type semiconductor; and
a first hybrid structure between the first source/drain and the substrate, the first hybrid structure including:
a first semiconductor feature, the first source/drain being in direct contact with the first semiconductor feature; and
a first isolation region between the first semiconductor feature and the substrate; and
a second transistor including:
a second stack of nanostructures on the substrate;
a second source/drain that is adjacent the second stack of nanostructures, the second source/drain including an n-type semiconductor; and
a second hybrid structure between the second source/drain and the substrate, the second hybrid structure including:
a second semiconductor feature, the second source/drain being on the second semiconductor feature; and
a second isolation region between the second semiconductor feature and the substrate.

9. The device of claim 8, wherein the first source/drain is in direct contact with the first isolation region.

10. The device of claim 8, wherein:
the first semiconductor feature extends to a first depth below a lower surface of the first source/drain; and
the first isolation region extends to a second depth below the lower surface that is at least half the first depth.

11. The device of claim 10, wherein:
the first depth is in a range of about 32 nanometers to about 46 nanometers; and
the second depth is in a range of about 12 nanometers to about 26 nanometers.

12. The device of claim 8, wherein the first isolation region has width in a range of about 2 nanometers to about 4 nanometers.

13. The device of claim 8, wherein the first semiconductor feature is in direct contact with the substrate.

14. The device of claim 8, wherein the first hybrid structure includes:
a first semiconductor layer between the first semiconductor feature and the substrate, wherein the first semiconductor layer has different etch selectivity than the first semiconductor feature and the substrate.

15. A method, comprising:
forming a stack of nanostructures over a substrate;
forming a source/drain opening to a first level below the stack of nanostructures;
forming an extended source/drain opening by extending the source/drain opening to a second level below the first level;
forming a first material layer in the extended source/drain opening;
forming a semiconductor feature in the extended source/drain opening adjacent the first material layer;
forming an isolation structure including forming an isolation opening in the first material layer; and
forming a source/drain region on the semiconductor feature and on respective sidewalls of the stack of nanostructures.

16. The method of claim 15, wherein the forming an isolation structure includes:
forming a dielectric layer in the isolation opening.

17. The method of claim 16, wherein the forming a dielectric layer includes forming the dielectric layer having a seam therein.

18. The method of claim 16, wherein the forming a dielectric layer includes forming the dielectric layer that partially fills the isolation opening.

19. The method of claim 15, wherein the forming a semiconductor feature includes forming the semiconductor feature that is in direct contact with the substrate.

20. The method of claim 15, wherein the forming a semiconductor feature includes forming the semiconductor feature extending to a third level between the first level and the second level, the first material layer being vertically between the semiconductor feature and the substrate.
